(19) United States
(12) Patent Application Publication
(10) Pub. No.: US 2025/0006467 A1
(43) Pub. Date: Jan. 2, 2025

(54) SUBSTRATE PROCESSING APPARATUS

(71) Applicant: PSK INC., Gyeonggi-do (KR)

(72) Inventors: Paul YANG, Gyeonggi-do (KR); Jung Hyun KANG, Gyeonggi-do (KR); Soo Yeong YANG, Gyeonggi-do (KR); Chi Young LEE, Gyeonggi-do (KR)

(21) Appl. No.: 18/293,321

(22) PCT Filed: Jul. 19, 2022
(86) PCT No.: PCT/KR2022/010489

§ 371 Date: Jan. 29, 2024

(30) Foreign Application Priority Data
Jul. 28, 2021 (KR) 10-2021-0099318

(51) Int. Cl. H01J 37/32

(52) U.S. Cl. CPC H01J 37/3244; H01J 37/3211; H01J 37/32119

(57) ABSTRACT

Provided is an apparatus for processing a substrate, the apparatus including: a housing having a processing space for processing a substrate; a window unit for covering an upper portion of the processing space so that the processing space is sealed; a support unit for supporting the substrate in the processing space; a gas supply unit including a nozzle for supplying gas to the processing space; and a plasma unit disposed outside the processing space, and generating plasma from the gas, in which the nozzle may include: a body formed with an internal space and an outlet for supplying the gas in the internal space to the processing space; and an insertion member inserted into a top end of the body.

### TECHNICAL FIELD

The present invention relates to a substrate processing apparatus, and more particularly to a substrate processing apparatus for processing a substrate by using plasma.

### BACKGROUND ART

Plasma is an ionized gas state composed of ions, radicals, electrons, and the like. Plasma is generated by very high temperatures, strong electric fields, or RF Electromagnetic Fields. The semiconductor device manufacturing process includes an ashing or etching process that removes a thin film on a substrate by using plasma. The ashing or etching process is performed by ion and radical particles contained in the plasma colliding or reacting with a film on the substrate.

In order to generate plasma, process gas needs be injected into a processing space. The process gas is provided as a plurality of gas of different types, depending on the needs of the process. Heterogeneous process gas should be uniformly mixed and supplied into the processing space to improve collision performance or reactivity with the film formed on the substrate. However, heterogeneous process gas is supplied to the processing space without being uniformly mixed with each other during the process of being supplied to the processing space. In addition, the heterogeneous process gas is not evenly distributed within the processing space and is concentrated in the center region of the substrate. As a result, the center region of the substrate is relatively over-ashed or over-etched compared to the edge regions. This is a factor that affects the ashing rate or etch rate of the substrate during the ashing or etching process.

### Technical Problem

The present invention aims to provide a substrate processing apparatus in which different types of process gas may be uniformly mixed.

Further, the present invention aims to provide a substrate processing apparatus in which mixed process gas may flow uniformly within a substrate processing space.

The problem to be solved by the present invention is not limited to the above-mentioned problems, and the problems not mentioned will be clearly understood by those skilled in the art from the present specification and the accompanying drawings.

### Technical Solution

An exemplary embodiment of the present invention provides an apparatus for processing a substrate, the apparatus including: a housing having a processing space for processing a substrate: a window unit for covering an upper portion of the processing space so that the processing space is sealed: a support unit for supporting the substrate in the processing space: a gas supply unit including a nozzle for supplying gas to the processing space; and a plasma unit disposed outside the processing space, and generating plasma from the gas, in which the nozzle may include: a body formed with an internal space and an outlet for supplying the gas in the internal space to the processing space; and an insertion member inserted into a top end of the body.

According to the exemplary embodiment, the insertion member may include a bottom plate formed with a through-hole penetrating vertically and a side plate extending upwardly from the bottom plate, and the insertion member may have an upper mixing space surrounded by the bottom plate and the side plate therein.

According to the exemplary embodiment, a region below the insertion member in the internal space may be provided as a lower mixing space, and when viewed from the front, a width of the upper mixing space and a width of the lower mixing space may be provided to be equal.

According to the exemplary embodiment, the body may be provided with a discharge region in which the outlets are formed, and the discharge region may be located at a lower end of the body and has a hemispherical shape.

According to the exemplary embodiment, the gas supply unit may further include a gas supply line which has one end connected to the insertion member to supply the gas to the internal space, and the gas supply line may include: a first gas supply line for supplying first gas to the internal space; and a second gas supply line for supplying second gas different from the first gas to the internal space.

According to the exemplary embodiment, the plasma unit may include: an inner coil part: an outer coil part provided to surround the inner coil part when viewed from above: an upper power source for applying power to the inner coil part and the outer coil part; and a ground plate disposed on top of the inner coil part and the outer coil part, and grounding the inner coil part and the outer coil part.

According to the exemplary embodiment, a region below the insertion member in the internal space may be provided as a lower mixing space, and an inner wall of the body may have a lower inner wall providing the lower mixing space and an upper inner wall providing a space into which the insertion member is inserted, and the upper inner wall may be provided stepped with respect to the lower inner wall, and a width of a space surrounded by the upper inner wall may be provided wider than a width of a space surrounded by the lower inner wall.

According to the exemplary embodiment, in a state where the insertion member is inserted into the upper inner wall, an inner surface of the insertion member and an inner surface of the lower inner wall may be provided to form the same side.

According to the exemplary embodiment, the insertion member may further include a catching plate extending from a top end of the side plate in a direction away from the internal space, and a bottom surface of the catching plate may be positioned on a top surface of the upper inner wall to be detachable from the body.

According to the exemplary embodiment, the nozzle may be installed in the window unit to penetrate an opening formed in the window unit.

According to the exemplary embodiment, a height of the insertion member may be 15 mm or more.

According to the exemplary embodiment, a distance from a bottom end of the insertion member to a bottom end of the body may be 5 mm or more.

Another exemplary embodiment of the present invention provides an apparatus for processing a substrate, the apparatus including: a housing having a processing space for processing a substrate: a support unit for supporting the substrate in the processing space: a gas supply unit for supplying gas including first gas and second gas different from the first gas to the processing space; and a plasma source for generating plasma from the gas supplied to the processing space, in which wherein the gas supply unit includes: a nozzle for supplying the gas to the processing space: a first gas supply line for supplying the first gas to the nozzle; and a second gas supply line for supplying the second gas to the nozzle, the nozzle includes: a body formed with an internal space and an outlet for supplying the gas in the internal space to the processing space; and an insertion member inserted into a top end of the body, the body is provided with a discharge region in which the outlets are formed, and the discharge region is located at a lower end of the body and has a hemispherical shape, the insertion member includes a bottom plate formed with a through-hole penetrating vertically and a side plate extending upwardly from the bottom plate, and the insertion member has an upper mixing space surrounded by the bottom plate and the side plate therein.

According to the exemplary embodiment, a region below the insertion member in the internal space may be provided as a lower mixing space, and an inner wall of the body may have a lower inner wall providing the lower mixing space and an upper inner wall providing a space into which the insertion member is inserted, and the upper inner wall may be provided stepped with respect to the lower inner wall, and a width of a space surrounded by the upper inner wall may be provided wider than a width of a space surrounded by the lower inner wall.

According to the exemplary embodiment, in a state where the insertion member is inserted into the upper inner wall, an inner surface of the insertion member and an inner surface of the lower inner wall may be provided to form the same side.

Still another exemplary embodiment of the present invention provides a nozzle unit for supplying a plurality of gas to a processing space which processes a substrate, the nozzle unit including: a body formed with an internal space and an outlet for supplying the plurality of gas within the internal space to the processing space; and an insertion member inserted into a top end of the body, in which the body is provided with a discharge region in which the outlets are formed, and the discharge region is located at a lower end of the body and has a hemispherical shape, the insertion member includes a bottom plate formed with a through-hole penetrating vertically and a side plate extending upwardly from the bottom plate, and the insertion member has an upper mixing space surrounded by the bottom plate and the side plate therein.

According to the exemplary embodiment, a region below the insertion member in the internal space may be provided as a lower mixing space, and an inner wall of the body may have a lower inner wall providing the lower mixing space and an upper inner wall providing a space into which the insertion member is inserted, and the upper inner wall may be provided stepped with respect to the lower inner wall, and a width of a space surrounded by the upper inner wall may be provided wider than a width of a space surrounded by the lower inner wall.

According to the exemplary embodiment, in a state where the insertion member is inserted into the upper inner wall, an inner surface of the insertion member and an inner surface of the lower inner wall may be provided to form the same side.

According to the exemplary embodiment, the insertion member may further include a catching plate extending from a top end of the side plate in a direction away from the internal space, and a bottom surface of the catching plate may be positioned on a top surface of the upper inner wall to be detachable from the body.

According to the exemplary embodiment, a height of the insertion member may be 15 mm or more, and a distance from a bottom end of the insertion member to a bottom end of the body may be 5 mm or more.

### Advantageous Effects

According to the exemplary embodiment of the present invention, different types of process gas may be uniformly mixed.

Furthermore, according to the exemplary embodiment of the invention, mixed process gas may flow uniformly within a substrate processing space.

Furthermore, according to the exemplary embodiment of the invention, the uniformity of processing of the substrate may be improved.

The effect of the present invention is not limited to the foregoing effects, and the not-mentioned effects will be clearly understood by those skilled in the art from the present specification and the accompanying drawings.

### DESCRIPTION OF DRAWINGS

FIG. 1 is a diagram schematically illustrating a substrate processing apparatus of the present invention.

FIG. 2 is a diagram schematically illustrating an exemplary embodiment of a process chamber that performs a plasma treatment process among process chambers of the substrate processing apparatus of FIG. 1.

FIG. 3 is a diagram schematically illustrating a perspective view of a nozzle unit of FIG. 2.

FIG. 4 is a diagram schematically illustrating a cutaway view in the X-X direction of the nozzle unit of FIG. 3.

FIG. 5 is a diagram schematically illustrating a body of FIG. 4.

FIG. 6 is a diagram schematically illustrating a cutaway perspective view of an insertion member of FIG. 2.

FIG. 7 is a diagram schematically illustrating process gas flowing within the nozzle unit of FIG. 2.

FIG. 8 is a diagram schematically illustrating process gas discharged from the nozzle unit of FIG. 2.

FIG. 9 is a diagram schematically illustrating process gas flowing within a processing space of FIG. 2.

### BEST MODE

Hereinafter, an exemplary embodiment of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

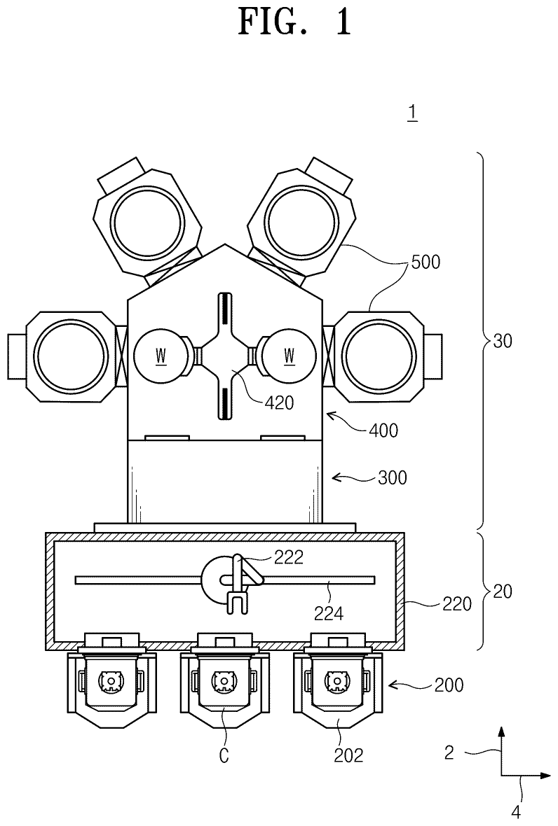

Hereinafter, an exemplary embodiment of the present invention will be described in detail with reference to FIGS. 1 to 9.

FIG. 1 is a diagram schematically illustrating a substrate processing apparatus of the present invention. Referring to FIG. 1, a substrate processing apparatus 1 includes an Equipment Front End Module (EFEM) 20 and a processing module 30. The equipment front end module 20 and the processing module 30 are disposed in one direction.

The equipment front end module 20 includes a load port 10 and a transfer frame 220. The load port 200 is disposed at the front of the equipment front end module 20 in a first direction 2. The load port 10 includes a plurality of support parts 202. Each support part 202 is arranged in a row in a second direction 4, on which a substrate W to be provided to the process and a carrier C (for example, cassette, or FOUP) in which the completely processed substrate W is accommodated are seated. In the carrier C, the substrate W to be provided to the process and the substrate W that has been completely processed are accommodated. The transfer frame 220 is disposed between the load port 200 and the processing module 30. The transfer frame 220 includes a first transfer robot 222 disposed therein and transferring the substrate W between the load port 200 and the processing module 30. The first transfer robot 222 moves along a transfer rail 224 provided in the second direction 4 to transfer the substrate W between the carrier C and the processing module 30.

The processing module 30 includes a load lock chamber 300, a transfer chamber 400, and a process chamber 500.

The load lock chamber 300 is disposed to be adjacent to the transfer frame 220. In one example, the load lock chamber 300 may be disposed between the transfer chamber 400 and the front end module 20. The load lock chamber 300 provides a waiting space for the substrate W to be provided to the process before the substrate W is transferred to the process chamber 500, or for the substrate W that has been completely processed before the substrate W is transferred to the front end module 20.

The transfer chamber 400 is disposed to be adjacent to the load lock chamber 300. The transfer chamber 400 has a polygonal body when viewed from above. In one example, the transfer chamber 400 may have a pentagonal body when viewed from above. On the outer side of the body, the load lock chamber 300 and the plurality of process chambers 500 are disposed along the circumference of the body. A passageway (not illustrated) is formed in each sidewall of the body through which the substrate W enters and exits, and the passageway connects the transfer chamber 400 to the load lock chamber 300 or the process chamber 500. Each passage is provided with a door (not illustrated) which opens/closes the passage to seal the interior. In the internal space of the transfer chamber 400, a second transfer robot 420 is arranged to transfer the substrate W between the load lock chamber 300 and the process chambers 500. The second transfer robot 420 transfers the unprocessed substrate W waiting in the load lock chamber 300 to the process chamber 500, or transfers the completely-processed substrate W to the load lock chamber 300. Then, the substrate W is transferred between the process chambers 500 to sequentially provide the substrate W to the plurality of process chambers 500. In one example, as illustrated in FIG. 1, when the transfer chamber 400 has a pentagonal body, the load lock chamber 300 is disposed on each of the sidewalls adjacent to the front end module 20, and the process chambers 500 are consecutively disposed on the remaining sidewalls. The shape of the transfer chamber 400 is not limited to, and may be provided in various forms depending on the process module required.

The process chamber 500 is disposed along the circumference of the transfer chamber 400. A plurality of process chambers 60 may be provided. Within each process chamber 500, process processing for the substrate W is performed. The process chamber 500 receives the substrate W from the second transfer robot 420, processes the substrate W, and provides the process-completed substrate W to the second transfer robot 420. The process processing performed in each process chamber 500 may differ from each other. Hereinafter, the process chamber 500 performing a plasma treatment process will be described in detail.

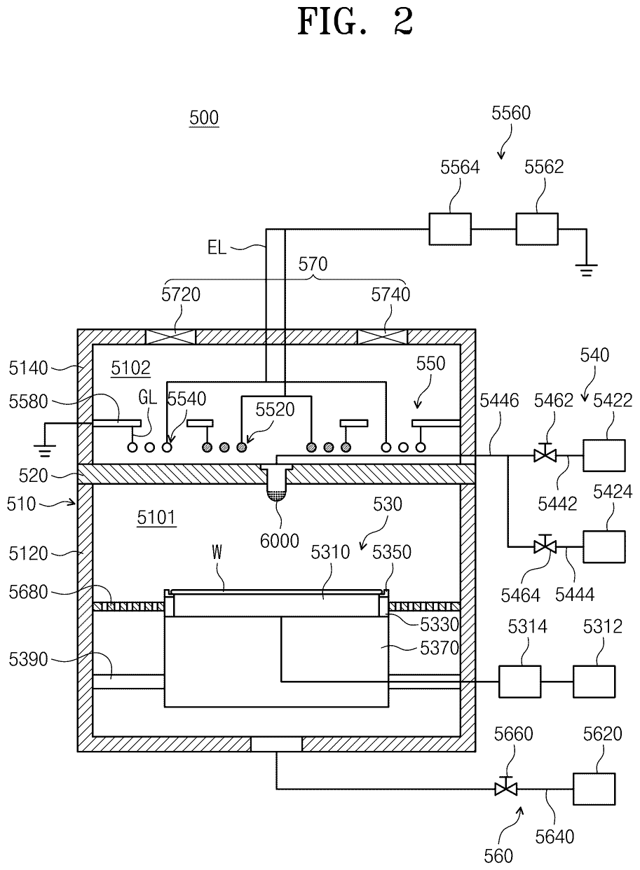

FIG. 2 is a diagram schematically illustrating a process chamber that performs a plasma treatment process among process chambers of the substrate processing apparatus of FIG. 1.

Referring to FIG. 2, the process chamber 500 performs a predetermined process on the substrate W by using plasma. In one example, a thin film on the substrate W may be etched or ashed. The thin film may be various types of films, such as a polysilicon film, an oxide film, or a silicon nitride film. Optionally, the thin film may be a natural oxide film or a chemically generated oxide film.

The process chamber 500 may include a housing 510, a window unit 520, a support unit 530, a gas supply unit 540, and a plasma unit 550.

The housing 510 may have a processing space 5101 where the substrate W is processed and an upper space 5102. The housing 510 may be provided of a metal material. The housing 510 may be provided of a material including aluminum. The housing 510 may be grounded. The housing 510 may include a lower body 5120 and an upper body 5140.

The lower body 5120 may have a top-open space therein. In one example, the lower body 5120 may have the shape of a barrel with an open top. The lower body 5120 may have a processing space 5101 inside in combination with a window unit 520 which will be described later. The upper body 5140 may have a bottom side open space therein. In one example, the upper body 5120 may have the shape of a barrel with an open bottom. The upper body 5140 may have the upper space 5102 in combination with the window unit 520 which will be described later.

The window unit 520 may be disposed on top of the lower body 5120. The window unit 520 may cover an open top surface of the lower body 5120. The window unit 520 may be combined with the lower body 5120 to form the processing space 5101. The window unit 520 may be disposed under the upper body 5140 to cover the open bottom side of the lower body 5140. The window units 520 may be combined with the upper body 5140 to form the upper space 5102. The upper space 5102 may be disposed above the processing space 5101. An opening may be formed in the window unit 520. In one example, an opening may be formed in the center of the window unit 520. In the opening formed in the window unit 520, a nozzle unit 6000 which will be described later may be installed. The nozzle unit 6000 installed in the window unit 520 may be provided to be detachable.

The processing space 5101 may be used as a space in which the support unit 530 described below supports the substrate W and the substrate W is processed. The upper space 5102 may be used as a space where an inner coil part 5520, an outer coil part 5540, and a ground plate 5580 which will be described later are disposed. The window unit 520 may be provided with the nozzle unit 6000 which will be described later. In one example, the nozzle unit 6000 may be provided in the center of the window unit 520.

The window unit 520 may be provided in a plate shape. The window unit 520 may seal the processing space 5101. The window unit 520 may include a dielectric substance window.

The support unit 530 may support the substrate W in the processing space 5101. The support unit 530 may be capable of chucking the substrate W. The support unit 530 may include a chuck 5310, an isolation ring 5330, a focus ring 5350, a cover ring 5370, and an interface cover 5390.

The chuck 5310 may have a seating surface that supports a bottom side of the substrate W. The chuck 5310 may be an ESC. The substrate W placed in the chuck 5310 may be a wafer. Power may be applied to the chuck 5310. For example, the chuck 5310 may be subjected to high frequency power applied by a lower power source 5312. Further, a first matcher 5314 may be installed between the lower power source 5312 and the chuck 5310 to perform a match on the high frequency power applied by the lower power source 5312.

An insulating ring 5330 may be provided to surround the chuck 5310 when viewed from above. On the top surface of the insulating ring 5330, a focus ring 5350 may be placed. The top surface of the focus ring 5350 may be stepped such that an inner height is lower than an outer height. On the inner side of the focus ring 5350, the bottom side of the edge region of the substrate W placed in the chuck 5310 may be placed. That is, the center region of the substrate W may be placed on a seating surface of the chuck 5310, and the edge region of the substrate W may rest on the top surface of the inner side of the focus ring 5350.

The cover ring 5370 may be disposed under the chuck 5310. The cover ring 5370 may have a generally barrel shape with an open top. The cover ring 5370 may be disposed under the chuck 5310 to form a lower space. The lower space may be provided with interface lines necessary to drive the support unit 530. These interface lines may be interconnected with external devices via an interface cover 5390, which has a space in communication with the lower space of the cover ring 5370.

The gas supply unit 540 may supply process gas to the processing space 5101. The process gas supplied by the gas supply unit 540 to the processing space 5101 may include at least one of CF₄, N₂, Ar, H₂, O₂, and O*. However, without limitation, the type of process gas supplied by the gas supply unit 540 to the processing space 5101 may be varied with known process gas.

The gas supply unit 540 may include a gas supply source 5420, a gas supply line 5440, a supply valve 5460, and the nozzle unit 6000.

The gas source 5420 may store process gas or deliver process gas to the gas supply line 5440 which will be described later. The gas supply source 5420 may include a first gas supply source 5422 and a second gas supply source 5424. A first gas supply source 5422 may store first gas or deliver first gas to a first gas supply line 5442 which will be described later. A second gas supply source 5424 may store second gas or deliver second gas to a second gas supply line 5444 which will be described later. The first gas and the second gas may be different types of gas.

The gas supply line 5440 may receive process gas from the gas supply source 5420. The gas supply line 5440 may include a first gas supply line 5442 and a second gas supply line 5444. One end of the first gas supply line 5442 may be connected to the nozzle unit 6000 which will be described later, and the other end of the first gas supply line 5442 may be connected to the first gas supply source 5422. One end of the second gas supply line 5444 may be connected to the nozzle unit 6000, and the other end of the second gas supply line 5444 may be connected to the second gas supply source 5424. In one example, one end of the first gas supply line 5442 and one end of the second gas supply line 5444 may be connected to an insertion member 6400 which will be described later.

Unlike the above example, the gas supply line 5440 may include the first gas supply line 5442, the second gas supply line 5444, and a main gas supply line 5446. One end of the main gas supply line 5446 is connected to the nozzle unit 6000 which will be described later. In one example, one end of the main gas supply line 5446 may be connected to the insertion member 6400 which will be described later. The main supply line 5446 may be branched into the first gas supply line 5442 and the second gas supply line 5444. The first gas supply line 5442 is connected to the first gas supply source 5422 to receive the first gas from the first gas supply source 5422. The second gas supply line 5444 is connected to the second gas source 5424 to receive the second gas from the second gas supply source 5424.

The supply valve 5460 may be installed on the gas supply line 5440. The supply valve 5440 may be an open/close valve. However, without limitation, the supply valve 5440 may be provided as a flow control valve. The supply valve 5460 may include a first supply valve 5462 and a second supply valve 5464. The first supply valve 5462 may be installed on the first gas supply line 5442. The second supply valve 5464 may be installed on the second gas supply line 5444.

While the above example describes controlling the amount of gas supplied to the processing space 5101 through the supply valve 5460, the present disclosure is not limited thereto. In one example, a mass flow controller may be installed in the gas supply line 5440 to control the amount of process gas supplied to the processing space 5101 through the gas supply line 5440.

In the example described above, it has been described that two gas supply sources 5420, two gas supply lines 5440, and two supply valves 5460 are provided. However, without limitation, three or more supply sources 5420, gas supply lines 5440, and supply valves 5460 may be provided depending on the type of process gas required. For ease of the description, the following describes an example where the process gas is provided as first gas and second gas, and the first gas supply line 5442 and the second gas supply line 5444 are branched from the gas supply line 5440.

The nozzle unit 6000 supplies first gas and second gas to the processing space 5101. The nozzle unit 6000 may supply the processing space 5101 with the first gas supplied from the first gas supply line 5442. The nozzle unit 6000 may supply the processing space 5101 with the second gas supplied from the second gas supply line 5444. The nozzle unit 6000 may mix the first gas and the second gas therein and supply the mixed gas to the processing space 5101. The nozzle unit 6000 may be installed in an opening formed in the center of the window unit 520. The nozzle unit 6000 may be provided to be detachable from the window unit 520.

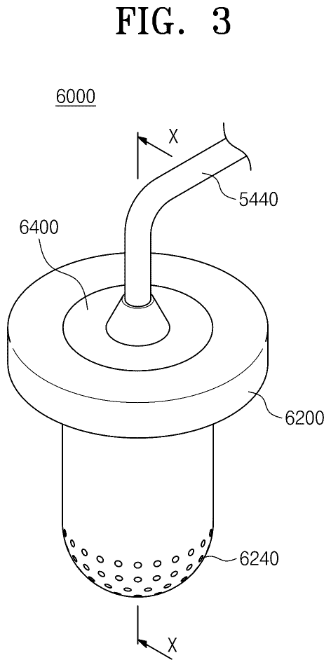

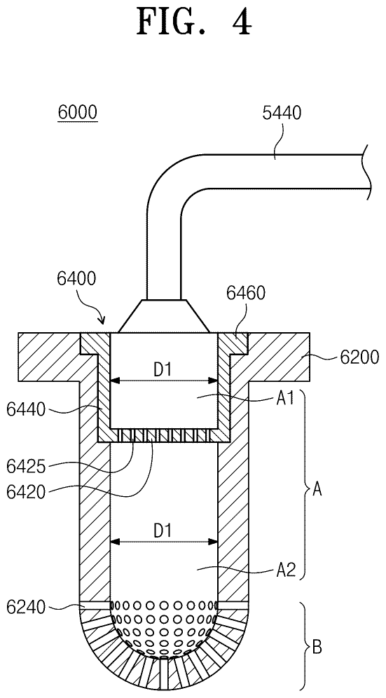

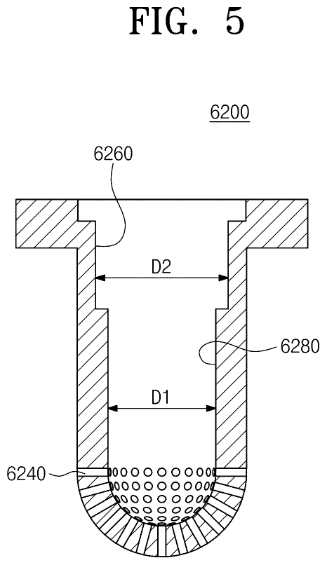

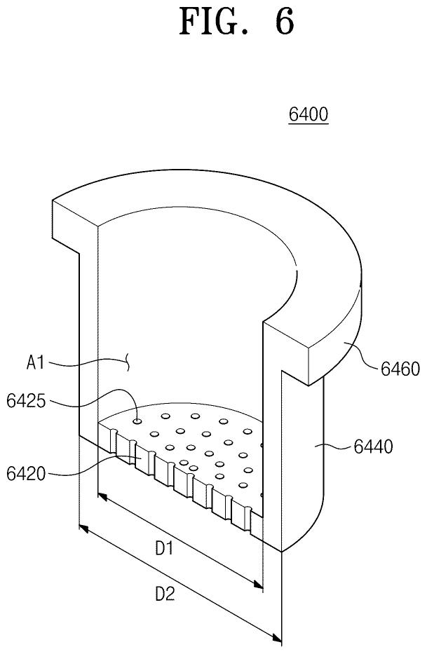

FIG. 3 is a diagram schematically illustrating a perspective view of the nozzle unit of FIG. 2. FIG. 4 is a diagram schematically illustrating a cutaway view in the X-X direction of the nozzle unit of FIG. 3. FIG. 5 is a diagram schematically illustrating the body of FIG. 4. FIG. 6 is a diagram schematically illustrating a cutaway perspective view of the insertion member of FIG. 2. Hereinafter, the nozzle unit 6000 will be described in detail with reference to FIGS. 3 to 6. Referring to FIGS. 3 to 6, the nozzle unit 6000 may include a body 6200 and an insertion member 6400.

The body 6200 has an inner space A in which the first gas and the second gas flow therein. The inner space A is provided as a space in which the first gas and the second gas supplied from the gas supply line 5440 flow. The inner space A is provided as a space where the first gas and the second gas are mixed with each other. The first gas and the second gas mixed in the inner space A are supplied to the processing space 5101.

A discharge region B is provided at the bottom end of the body 6200. The discharge region B may be provided in a generally hemispherical shape. In one example, the discharge region B may be provided in a hemispherical shape curved downwardly with respect to the ground. In the discharge region B, an outlet 6240 is formed to supply the first gas and the second gas flowing in the inner space A to the processing space 5101. The outlet 6240 may be provided with at least one outlet. In one example, the outlets 6240 may be provided in a plurality. Each of the outlets 6240 may be provided with a diameter of 1 mm or more. The plurality of outlets 6240 may penetrate from an inner wall of the body 6200 to an outer wall of the body 6200. The plurality of outlets 6240 may be provided spaced apart from each other on the discharge region B, which is provided in a hemispherical shape.

A middle end of the body 6200 may extend from the bottom of the body 6200 in an upward direction. The middle end of the body 6200 may be generally provided in the shape of a column having an internal space. The middle end of the body 6200 may have an internal space A therein. In one example, the middle end of the body 6200 may be provided with an outer diameter of 25 mm or more.

A top end of the body 6200 may extend from the middle end of the body 6200 in a direction away from the center of the body 6200. The top end of the body 6200 may be provided in a generally disk-like shape.

The bottom end and the middle end of the body 6200 may penetrate the opening formed in the window unit 520. A bottom surface of the top end of the body 6200 may be positioned on the window unit 520. Accordingly, the body 6200 is detachably provided to the window unit 520. The nozzle unit 6000 is detachably provided on the window unit 520.

The inner wall of the body 6200 may have an upper inner wall 6260 and a lower inner wall 6280. The upper inner wall 6260 provides a space into which the insertion member 6400 is inserted. The space surrounded by the upper inner wall 6260 may be the space into which the insertion member 6400 is inserted. In the state where the insertion member 6400 is inserted into the top end of the body 6200, the space surrounded by the lower inner wall 6280 may be provided as a lower mixing space A2.

The upper inner wall 6260 may be provided stepped with respect to the lower inner wall 6240. In one example, the upper inner wall 6260 may be provided stepped in a direction away from the lower inner wall 6240. A width D2 of the space surrounded by the upper inner wall 6260 may be provided to be wider than a width D1 of the space surrounded by the lower inner wall 6280. In one example, the lower inner wall 6280 may be provided with a thickness of 5 mm or more.

The insertion member 6400 is inserted into the body 6200. The insertion member 6400 may be surrounded by the upper inner wall 6260 as it is inserted into the body 6200. The insertion member 6400 may be inserted into an insertion space formed in the upper center of the body 6200. The insertion member 6400 may have an internal space. The space provided in the interior of the insertion member 6400 may be provided as an upper mixing space A1 which will be described later. A gas supply line 5440 may be connected to the top end of the insertion member 6400.

The insertion member 6400 may include a bottom plate 6420, a side plate 6440, and a catching plate 6460. The bottom plate 6420 has a through-hole 6425 formed through the bottom plate 6420 up and down. The through-hole 6425 may be provided with at least one through-hole. In one example, the through holes 6425 may be provided in plurality. The side plate 6440 extends upwardly from the bottom plate 6420. The insertion member 6400 has the upper mixing space A1 that is surrounded by the bottom plate 6420 and the side plate 6440. The catching plate 6460 extends from the top end of the side plate 6440 in a direction away from the upper mixing space A1. In the state where the insertion member 6400 is inserted into the body 6200, the bottom surface of the catching plate 6460 may be positioned on the top end surface of the upper inner wall 6260. Accordingly, the insertion member 6400 may be detachably provided on the body 6200.

In the state where the insertion member 6400 is inserted into the upper inner wall 6260, the inner surface of the side plate 6440 of the insertion member 6400 and the inner surface of the lower inner wall 6280 may be provided to form the same side of each other. That is, the thickness of the side plate 6440 may have a value obtained by subtracting the width D1 of the space surrounded by the lower inner wall 6280 from the width D2 of the space surrounded by the upper inner wall 6260. Thus, in the state where the insertion member 6400 is inserted into the upper inner wall 6260, the width of the upper mixing space A1 and the width of the lower mixing space A2 may be provided to be the same when viewed from the front. The height of the insertion member 6400 may be provided as 15 mm or more. The distance from the bottom end of the insertion member 6400 to the bottom end of the body 6200 may be provided as 5 mm or more. This is to ensure sufficient space for the first gas and the second gas to be mixed in the upper mixing space A1 and the lower mixing space A2 formed by the insertion member 6400.

The bottom end and the middle end of the body 6200 may be inserted into the opening formed in the window unit 520. The lower surface of the top end of the body 6200 may be positioned on the window unit 520. Accordingly, the body 6200 may be detachably provided to the window unit 520.

The body 6200 and the insertion member 6400 may be provided from a material, such as oxide ceramic, nitride ceramic, or stainless steel. The body 6200 and the insertion member 6400 may be coated with a material, such as a yttria-based compound or quartz. However, without limitation, the body 6200 and the insertion member 6400 may be coated with a thin film having a high resistivity and good corrosion resistance. The coating layer on the body 6200 and the insertion member 6400 may be formed by physical vapor deposition (sputtering, evaporating), chemical vapor deposition (CVD), spraying, or electroplating.

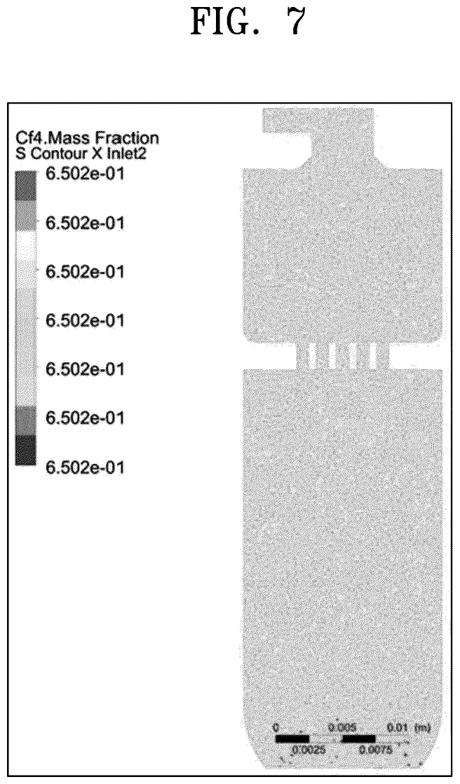

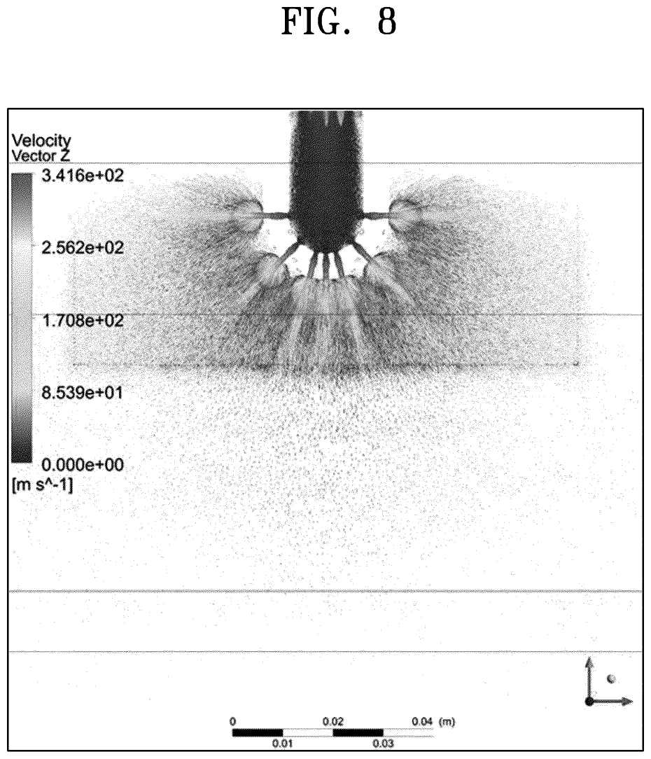

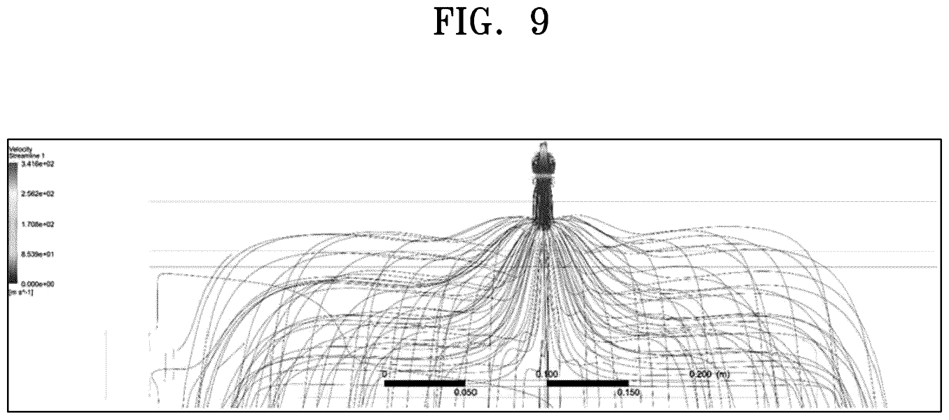

FIG. 7 is a diagram schematically illustrating process gas flowing within the nozzle unit of FIG. 2. FIG. 8 is a diagram schematically illustrating process gas discharged from the nozzle unit of FIG. 2. FIG. 9 is a diagram schematically illustrating process gas flowing within the processing space of FIG. 2.

Referring to FIG. 7, the nozzle unit according to the exemplary embodiment of the present invention is divided into the upper mixing space A1 and the lower mixing space A2 by the insertion member 6400. That is, the inner space A of the body 6200 may be divided into the upper mixing space A1 and the lower mixing space A2 by the insertion member 6400. Accordingly, the first gas and the second gas flowing from the gas supply line 5440 are primarily mixed in the upper mixing space A1. The first and second gases, which are preliminarily mixed in the upper mixing space A1, move to the lower mixing space A2 through the through-hole 6425 formed in the bottom plate 6420 of the insertion member 6400. The first gas and the second gas that have been primarily mixed in the upper mixing space A1 are mixed again in the lower mixing space A2. Thus, before the first gas and the second gas with different masses are supplied to the processing space 5101, a space for the first and second gases to be mixed with each other may be preliminarily reserved.

Particular, when heavier mass gas is supplied to the processing space 5101 as process gas, the heavier mass gas is discharged directly into the processing space 5101 due to its weight. Thus, the heavier mass gas is not mixed with the relatively lighter mass gas and is supplied into the processing space 5101 separately. According to the exemplary embodiment of the present invention, space may be provided in the upper mixing space A1 and the lower mixing space A2 for mixing different gases, for example, the first gas and the second gas. Thus, the problem that different gases with different masses are supplied directly to the processing space 5101 without mixing with each other may be solved.

That is, a vortex of process gas is formed within the upper mixing space A1 surrounded by the bottom plate 6420 and the side plate 6440 of the insertion member 6400, such that heterogeneous process gas having different masses may be mixed primarily. Subsequently, a vortex of process gas is formed within the lower mixing space A2 formed by the sidewalls of the body 6200 and the insertion member 6400, such that the process gas that is primarily mixed with each other may be mixed secondarily. Thus, the problem that gas with a heavy mass cannot be mixed with gas with a relatively light mass within the nozzle unit 6000 and is supplied to the processing space 5101 may be solved.

Referring to FIGS. 8 and 9, the discharge region 6220 according to the exemplary embodiment of the present invention may be provided in a hemispherical shape. In addition, the outlets 6240 may be provided in the discharge region 6220. Heterogeneous process gas may be uniformly mixed within the upper mixing space A1 and the lower mixing space A2, and the mixed process gas may be uniformly discharged onto the processing space 5101 by the discharge region 6220 provided at the bottom end of the nozzle unit 6000. That is, since the discharge region 6220 is provided in a hemispherical shape, it is possible to supply uniformly mixed process gas to the entire region of the processing space 5101, as illustrated in FIGS. 8 and 9.

Further, since the insertion member 6400 is provided to be detachable from the body 6200, maintenance may be easily performed on the insertion member 6400 in the event that the insertion member 6400 becomes contaminated with process gas supplied from the gas supply line 5440. Further, the nozzle unit 6000 is provided to be detachable from the window unit 520, so that maintenance on the nozzle unit 6000 may be easily performed.

The plasma unit 550 may generate plasma from process gas supplied to the processing space 5101. In one example, the plasma unit 550 may generate plasma from the first gas and the second gas supplied to the processing space 5101. The plasma unit 550 may be disposed outside of the processing space 5101. According to the exemplary embodiment of the present invention, the plasma unit 550 may be configured as an ICP type. The plasma unit 550 may include an inner coil part 5520, an outer coil part 5540, a power application unit 5560, a ground plate 5580, and an electric line EL.

The inner coil part 5520 and the outer coil part 5540 may be disposed in the upper space 5102. The inner coil part 5520 and the outer coil part 5540 may receive high frequency power from the power application unit 5560 described later to generate plasma from the process gas including the first gas and the second gas supplied to the processing space 5101.

The inner coil part 5520 may be disposed at a position corresponding to a center region of the processing space 5101, when viewed from above. The inner coil part 5520 may be provided in a ring shape. The outer coil part 5540 may be disposed at a position corresponding to an edge region of the processing space 5101 when viewed from above. In one example, the outer coil part 5540 may be provided to surround the inner coil part 5520 when viewed from above. The outer coil part 5540 may be provided in a ring shape.

The above-described exemplary embodiment is described by way of example, but is not limited to, the inner coil part 5520 and the outer coil part 5540 being provided in the upper space 5102. In one example, the inner coil part 5520 and the outer coil part 5540 may be disposed at side portions of the process chamber 500. In some exemplary embodiments, any one of the inner coil part 5520 and the outer coil part 5540 may be disposed at a top portion of the process chamber 500 and the other may be disposed at a side portion of the process chamber 500. As long as the inner coil part 5520 and the outer coil part 5540 generate plasma within the process chamber 500, the position of the inner coil part 5520 and the outer coil part 5540 is not limited.

At one end of the inner coil part 5520, a power terminal to which the electric line EL described below is connected may be formed. At the other end of the inner coil part 5520, a ground terminal to which a ground line GL described below is connected may be formed. A power terminal to which the electric line EL is connected may be formed at one end of the outer coil part 5540, and a ground terminal to which the ground line GL is connected may be formed at the other end of the outer coil part 5540.

The inner coil part 5520 and the outer coil part may 5540 may be provided from a metallic material including at least one of copper, aluminum, tungsten, silver, gold, platinum, and iron. The surfaces of the inner coil part 5520 and the outer coil part 5540 may be coated with a metallic material including at least one of silver, gold, and platinum. The coating layer may be a metal with low resistivity and good thermal conductivity. The coating layer may have a thickness of 20 micrometers or more. The coating layer may be formed by physical vapor deposition (sputtering, evaporating) or chemical vapor deposition (CVD), spraying, electroplating, or the like.

The power application unit 5560 may apply high frequency power to the inner coil part 5520 and the outer coil part 5540. The power application portion 5560 may include an upper power source 5562 and a second matcher 5564. The upper power source 5562 may be a high frequency power source. The second matcher 5564 may perform matching for the high frequency power applied by the upper power source 5562 to the inner coil part 5520 and the outer coil part 5540. One end of the electric line EL transmitting the high frequency power generated by the upper power source 5562 may be connected to the power terminal connected to the inner coil part 5520 and the power terminal connected to the outer coil part 5540.

The ground plate 5580 may be provided in the upper space 5102. The ground plate 5580 may be provided from a metal material including at least one of aluminum, copper, and iron. The ground plate 5580 may have a thickness of 3 mm or more. The ground plate 5580 may be disposed on top of the inner coil part 5520 and the outer coil part 5540. The ground plates 5580 may be spaced apart from each other above the inner coil part 5520 and the outer coil part 5540. In one example, the ground plate 5580 may be disposed at an interval of 50 nm or more from the inner coil part 5520 and the outer coil part 5540. The ground plate 5580 may be grounded. The ground plate 5580 may ground the inner coil part 5520 and the outer coil part 5540. An opening may be formed in the ground plate 5580 to allow airflow supplied to the upper space 5102 by a fan unit 570 described below to circulate freely in the upper space 5102. For example, when viewed from above, a circle-shaped opening may be formed in a center region of the ground plate 5580. Additionally, a plurality of arc-shaped openings may be formed in the region surrounding the center region of the ground plate 5580 when viewed from above. The arc-shaped openings formed in the region surrounding the center region of the ground plate 5580 may be formed in the ground plate 5580 at a position that overlaps with a first fan 5720 or a second fan 5740, as described below, when viewed from above.

The ground line GL may electrically connect the ground plate 5580 and the inner coil part 5520 to each other. The ground line GL may electrically connect the ground plate 5580 and the outer coil part 5540 to each other. The ground lines GL may be provided in plurality. The ground lines GL may be provided in plurality, such that one end of each of the ground lines GL is connected to the ground plate 5580, and the other end of each of the ground lines GL is connected to a ground terminal. The ground lines GL may be equally spaced along a circumferential direction with respect to the center of the ground plate 5580 when viewed from above. In one example, the ground lines GL may be disposed symmetrically about the center of the ground plate 5580 when viewed from above.

A controller (not illustrated) may control configurations of the substrate processing apparatus. For example, the controller may control the support unit 530, the gas supply unit 540, the plasma unit 550, a gas exhaust unit 560, and the fan unit 570. Further, the controller may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The gas exhaust unit 400 may exhaust process gas supplied to the processing space 5101, and process by-products that may be generated during the process of processing the substrate W, from the processing space 5101 through the exhaust hole 5160 formed on the bottom surface of the housing 510. The gas exhaust unit 560 may include a decompression member 5620, a decompression line 5640, a decompression valve 5660, and an exhaust baffle 5680.

The decompression member 5620 may provide decompression to the processing space 5101. The decompression member 5620 may be a pump. However, the decompression member 5620 is not limited thereto, and may be variously modified with any known device capable of providing decompression to the processing space 5101. The decompression provided by the decompression member 5620 may be delivered to the processing space 5101 through the decompression line 5640. Additionally, the decompression valve 430 may be installed in the decompression reducing line 5640. The decompression valve 430 may be an open/close valve. However, the decompression valve 5640 is not limited thereto, and may be provided as a flow control valve. The exhaust baffle 5680 may have a ring shape when viewed from above. The exhaust baffle 5680 may be provided to surround the support unit 530 when viewed from above. A plurality of exhaust holes may be formed in the exhaust baffle 5680.

The fan unit 570 may provide airflow to the upper space 5102. The fan unit 570 may provide temperature- and humidity-controlled airflow to the upper space 5102. The fan unit 570 may act as a cooler to prevent the temperature of the upper space 5102 from becoming excessively high. The fan unit 570 may include a first fan 5720 and a second fan 5740. The first fan 5720 and the second fan 5740 may provide airflow to the upper space 5102 from different locations. The first fan 5720 and the second fan 5740 may provide airflow in a downward direction into the upper space 5102.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in the specific application field and use of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a housing having a processing space for processing a substrate;
a window unit for covering an upper portion of the processing space so that the processing space is sealed;
a support unit for supporting the substrate in the processing space;
a gas supply unit including a nozzle for supplying gas to the processing space; and
a plasma unit disposed outside the processing space, and generating plasma from the gas,
wherein the nozzle includes:
a body formed with an internal space and an outlet for supplying the gas in the internal space to the processing space; and
an insertion member inserted into a top end of the body.

2. The apparatus of claim 1, wherein the insertion member includes a bottom plate formed with a through-hole penetrating vertically and a side plate extending upwardly from the bottom plate, and
the insertion member has an upper mixing space surrounded by the bottom plate and the side plate therein.

3. The apparatus of claim 2, wherein a region below the insertion member in the internal space is provided as a lower mixing space, and
when viewed from the front, a width of the upper mixing space and a width of the lower mixing space are provided to be equal.

4. The apparatus of claim 3, wherein the body is provided with a discharge region in which the outlets are formed, and
the discharge region is located at a lower end of the body and has a hemispherical shape.

5. The apparatus of claim 4, wherein the gas supply unit further includes a gas supply line which has one end connected to the insertion member to supply the gas to the internal space, and
the gas supply line includes:
a first gas supply line for supplying first gas to the internal space; and
a second gas supply line for supplying second gas different from the first gas to the internal space.

6. The apparatus of claim 5, wherein the plasma unit includes:
an inner coil part;
an outer coil part provided to surround the inner coil part when viewed from above;
an upper power source for applying power to the inner coil part and the outer coil part; and
a ground plate disposed on top of the inner coil part and the outer coil part, and grounding the inner coil part and the outer coil part.

7. The apparatus of claim 2, wherein a region below the insertion member in the internal space is provided as a lower mixing space, and
an inner wall of the body has a lower inner wall providing the lower mixing space and an upper inner wall providing a space into which the insertion member is inserted, and
the upper inner wall is provided stepped with respect to the lower inner wall, and a width of a space surrounded by the upper inner wall is provided wider than a width of a space surrounded by the lower inner wall.

8. The apparatus of claim 7, wherein in a state where the insertion member is inserted into the upper inner wall, an inner surface of the insertion member and an inner surface of the lower inner wall are provided to form the same side.

9. The apparatus of claim 1, wherein the insertion member is provided to be detachable from a top end of the body.

10. The apparatus of claim 2, wherein the nozzle is installed in the window unit to penetrate an opening formed in the window unit,
the insertion member further includes a catching plate extending from a top end of the side plate in a direction away from the internal space, and
a bottom surface of the catching plate is positioned on a top surface of the window unit.

11. The apparatus of claim 1, wherein a height of the insertion member is 15 mm or more.

12. The apparatus of claim 1, wherein a distance from a bottom end of the insertion member to a bottom end of the body is 5 mm or more.

13. An apparatus for processing a substrate, the apparatus comprising:
a housing having a processing space for processing a substrate;
a support unit for supporting the substrate in the processing space;
a gas supply unit for supplying gas including first gas and second gas different from the first gas to the processing space; and
a plasma source for generating plasma from the gas supplied to the processing space,
wherein the gas supply unit includes:
a nozzle for supplying the gas to the processing space;
a first gas supply line for supplying the first gas to the nozzle; and
a second gas supply line for supplying the second gas to the nozzle,
the nozzle includes:
a body formed with an internal space and an outlet for supplying the gas in the internal space to the processing space; and
an insertion member inserted into a top end of the body,
the body is provided with a discharge region in which the outlets are formed, and
the discharge region is located at a lower end of the body and has a hemispherical shape,
the insertion member includes a bottom plate formed with a through-hole penetrating vertically and a side plate extending upwardly from the bottom plate, and
the insertion member has an upper mixing space surrounded by the bottom plate and the side plate therein.

14. The apparatus of claim 13, wherein a region below the insertion member in the internal space is provided as a lower mixing space, and
an inner wall of the body has a lower inner wall providing the lower mixing space and an upper inner wall providing a space into which the insertion member is inserted, and
the upper inner wall is provided stepped with respect to the lower inner wall, and a width of a space surrounded by the upper inner wall is provided wider than a width of a space surrounded by the lower inner wall.

15. The apparatus of claim 14, wherein in a state where the insertion member is inserted into the upper inner wall, an inner surface of the insertion member and an inner surface of the lower inner wall are provided to form the same side.

16. A nozzle unit for supplying a plurality of gas to a processing space which processes a substrate, the nozzle unit comprising:
a body formed with an internal space and an outlet for supplying the plurality of gas within the internal space to the processing space; and
an insertion member inserted into a top end of the body,
wherein the body is provided with a discharge region in which the outlets are formed, and
the discharge region is located at a lower end of the body and has a hemispherical shape,
the insertion member includes a bottom plate formed with a through-hole penetrating vertically and a side plate extending upwardly from the bottom plate, and
the insertion member has an upper mixing space surrounded by the bottom plate and the side plate therein.

17. The nozzle unit of claim 16, wherein a region below the insertion member in the interior space is provided as a lower mixing space, and
an inner wall of the body has a lower inner wall providing the lower mixing space and an upper inner wall providing a space into which the insertion member is inserted, and
the upper inner wall is provided stepped with respect to the lower inner wall, and a width of a space surrounded by the upper inner wall is provided wider than a width of a space surrounded by the lower inner wall.

18. The nozzle unit of claim 17, wherein in a state where the insertion member is inserted into the upper inner wall, an inner surface of the insertion member and an inner surface of the lower inner wall are provided to form the same side.

19. The nozzle unit of claim 16, wherein the insertion member is provided to be detachable from a top end of the body.

20. The nozzle unit of claim 16, wherein a height of the insertion member is 15 mm or more, and a distance from a bottom end of the insertion member to a bottom end of the body is 5 mm or more.
